(19) United States
(12) Patent Application Publication
(10) Pub. No.: US 2009/0177942 A1
(43) Pub. Date: Jul. 9, 2009

(54) SYSTEMS AND METHODS FOR MEDIA CONTAINER FILE GENERATION

(75) Inventors: Miska Matias Hannuksela, Ruutana (FI); Jani Peltotalo, Tampere (FI)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/350,853

(22) Filed: Jan. 8, 2009

Related U.S. Application Data
(60) Provisional application No. 61/020,123, filed on Jan. 9, 2008.

(51) Int. Cl. H03M 13/05; G06F 17/30

(52) U.S. Cl. 714/752; 707/104.1; 714/E11.04; 707/E17.009

(57) ABSTRACT

A method includes organizing a first media source block in the media container file; calculating forward error correction (FEC) redundancy data based on the first media source block; organizing the FEC redundancy data in at least one FEC reservoir in the media container file; providing, in the media container file, meta data providing an association between the first media source block and the at least one FEC reservoir; storing the first media source block as a first elementary item in the media container file; and providing, in the media container file, information that the first elementary item comprises the first media source block

### BACKGROUND OF THE INVENTION

The present invention relates generally to the field of electronic communication and, more particularly, to generation of media container files.

### SUMMARY OF THE INVENTION

One aspect of the invention relates to a method comprising organizing a first media source block in the media container file; calculating forward error correction (FEC) redundancy data based on the first media source block; organizing the FEC redundancy data in at least one FEC reservoir in the media container file; providing, in the media container file, meta data providing an association between the first media source block and the at least one FEC reservoir; storing the first media source block as a first elementary item in the media container file; and providing, in the media container file, information that the first elementary item comprises the first media source block.

In one embodiment, the method further comprises providing a media source file; and organizing the media source file into the first media source block and any number of other media source blocks. The first media source block may comprise more than one contiguous portion of the media source file.

In another aspect, the invention relates to a media content server comprising a media block manager for organizing a first media source block in the media container file; a forward error correction (FEC) codec for calculating FEC redundancy data based on the first media source block; an FEC data manager coupled to the FEC codec for organizing the FEC redundancy data in at least one FEC reservoir in the media container file; a meta data manager for providing, in the media container file, meta data providing an association between the first media source block and the at least one FEC reservoir; a media container file manager for storing the first media source block as a first elementary item in the media container file; and a media source block information manager for providing, in the media container file, information that the first elementary item comprises the first media source block.

In another aspect of the invention, an apparatus comprises a processor; and a memory unit communicatively connected to the processor. The memory unit includes computer code for organizing a first media source block in the media container file; computer code for calculating forward error correction (FEC) redundancy data based on the first media source block; computer code for organizing the FEC redundancy data in at least one FEC reservoir in the media container file; computer code for providing, in the media container file, meta data providing an association between the first media source block and the at least one FEC reservoir; computer code for storing the first media source block as a first elementary item in the media container file; and computer code for providing, in the media container file, information that the first elementary item comprises the first media source block.

In another aspect of the invention, a program product, embodied on a computer-readable medium, comprises computer code for performing the following steps: organizing a first media source block in the media container file; calculating forward error correction (FEC) redundancy data based on the first media source block; organizing the FEC redundancy data in at least one FEC reservoir in the media container file; providing, in the media container file, meta data providing an association between the first media source block and the at least one FEC reservoir; storing the first media source block as a first elementary item in the media container file; and providing, in the media container file, information that the first elementary item comprises the first media source block.

### BRIEF DESCRIPTION OF THE DRAWINGS

FIG. 1 is an illustration of the hierarchy of multimedia file formats;

FIG. 2 is an illustration of a simplified file structure according to the ISO base media file format.

FIG. 3 is a schematic illustration of a file containing three alternative hint tracks with different FEC overhead for a source file;

FIG. 4 is a graphical representation of a generic multimedia communication system within which various embodiments of the present invention may be implemented;

FIG. 5 illustrates an exemplary flow diagram showing a media container file generation method according to an embodiment of the present invention;

FIG. 6 illustrates an exemplary flow diagram showing a media server operation method in accordance with embodiments of the present invention;

FIG. 7 illustrates an exemplary media container file;

FIG. 8 illustrates an exemplary communication system using a media container file in accordance with embodiments of the present invention;

FIG. 9 is a perspective view of an electronic device that can be used in conjunction with the implementation of various embodiments; and

FIG. 10 is a schematic representation of the circuitry which may be included in the electronic device of FIG. 9.

### DETAILED DESCRIPTION OF THE PREFERRED EMBODIMENTS

File Delivery over Unidirectional Transport (FLUTE), which is discussed at Internet Engineering Task Force (IETF) Request for Comments (RFC) No. 3926 (www.ietf.org/rfc/rfc3926.txt), has been widely adopted as the file delivery protocol for multicast and broadcast applications. FLUTE is based on the Asynchronous Layered Coding (ALC) protocol, which is discussed in the IETF RFC 3450 (www.ietf.org/rfc/rfc3450.txt), and the Layered Coding Transport (LCT) protocol, which is discussed in the IETF RFC 3451 (www.ietf.org/rfc/rfc3451.txt).

LCT provides transport level support for reliable content delivery and stream delivery protocols. ALC is a protocol instantiation of the LCT building block, and it serves as a base protocol for massively scalable reliable multicast distribution of arbitrary binary objects. FLUTE builds on top of ALC/LCT and defines a protocol for unidirectional delivery of files. FLUTE therefore inherits all of the functionalities defined in the ALC and LCT protocols.

LCT defines the notion of LCT channels to allow for massive scalability. The LCT scalability has been designed based on the Receiver-driven Layered Multicast (RLM) principle, where receivers are responsible of implementing an appropriate congestion control algorithm based on the adding and removing of layers of the delivered data. The sender sends the data into different layers, with each being addressed to a different multicast group.

In LCT, one or multiple channels may be used for the delivery of the files of a FLUTE session. A great flexibility is given to the FLUTE sender with regard to how the data is partitioned among the LCT channels. A common use case is to send the same data on all different LCT channels but at different bitrates. Additionally, the FLUTE sender may act intelligently to enable receivers to acquire all files of the FLUTE session by joining all channels for a shorter time than is normally required with one channel. In such a case, the data sent over each channel complements the data of other channels.

FLUTE defines a File Delivery Table (FDT), which carries metadata associated with the files delivered in the ALC/LCT session, and provides mechanisms for in-band delivery and updates of FDT. In contrast, ALC/LCT relies on other means for out-of-band delivery of file metadata, e.g., an electronic service guide that is normally delivered to clients well in advance of the ALC/LCT session combined with update fragments that can be sent during the ALC/LCT session.

The use of Forward Error Correction (FEC) codes is a classical solution to improve the reliability of multicast and broadcast transmissions in a packet erasure channel. FEC codes can be divided to systematic and non-systematic codes. With a systematic FEC codes, the first portion of a FEC encoding block consists of source symbols, i.e., the original user data for the given block, while the remaining symbols for the block consist of parity symbols generated by FEC encoder. In this case, the receiver must receive any set of encoding symbols equal or slightly more (depending on the used FEC encoding scheme) in number than the number of source symbols. When non-systematic FEC codes are used, all symbols for the block consist of parity symbols generated by FEC encoder. In this case, the receiver must receive a sufficient number of symbols to reconstruct the original user data for the given block via FEC decoder. There exists couple alternative systematic FEC encoding schemes, Raptor FEC (named MBMS FEC in 3GPP TS 26.346) being the most widely used among different standardization organizations.

With MBMS FEC the operation of an FEC encoder is divided into several steps. First, the source file is divided into Z≧1 source blocks and FEC encoding is applied independently to each source block. Next, each source block is divided into N≧1 contiguous sub-blocks. After that, each sub-block is divided into K sub-symbols and the mth symbol of a source block consists of the concatenation of mth sub-symbol from each of the sub-blocks. It should be noted that when N>1, then a symbol does not comprise a contiguous portion of the object, e.g., a symbol cannot be formed by copying a continuous range of bytes from the object. This happens when the source file size is bigger than the target sub-block size (the recommended value of which is 256 KB). Finally, FEC encoder generates desired number of parity symbols for each source blocks that consist of K source symbols.

It is not necessary for the receiver to know the total number of parity symbols (per source block) with MBMS FEC. So, the receiver receives some set of encoding symbols slightly more in number than the number of source symbols, and feeds those to an FEC decoder. From these encoding symbols the FEC decoder generates K source symbols, divides each source symbol to N sub-symbols, and composes N sub-blocks which can be concatenated to re-establish the original source block.

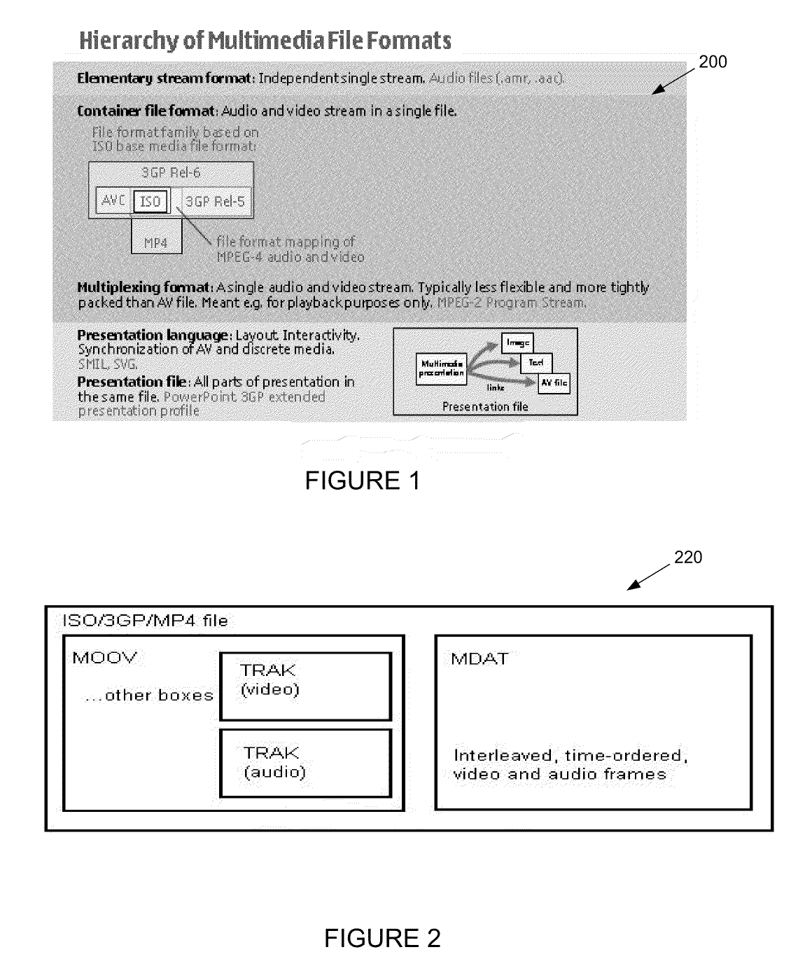

The multimedia container file format is an important element in the chain of multimedia content production, manipulation, transmission and consumption. There are substantial differences between the coding format (a.k.a. elementary stream format) and the container file format. The coding format relates to the action of a specific coding algorithm that codes the content information into a bitstream. The container file format comprises means of organizing the generated bitstream in such way that it can be accessed for local decoding and playback, transferred as a file, or streamed, all utilizing a variety of storage and transport architectures. Furthermore, the file format can facilitate interchange and editing of the media as well as recording of received real-time streams to a file. The hierarchy of multimedia file formats 200 is illustrated in FIG. 1.

Available media file format standards include ISO base media file format (ISO/IEC 14496-12), MPEG-4 file format (ISO/IEC 14496-14, also known as the MP4 format), AVC file format (ISO/IEC 14496-15) and 3GPP file format (3GPP TS 26.244, also known as the 3GP format). There is also a project in MPEG for development of the SVC file format, which will become an amendment to AVC file format. In a parallel effort, MPEG specified a hint track format for FLUTE (IETF RFC 3926) and ALC (IETF RFC 3450) sessions, which will be a part of Amendment 2 of ISO base media file format.

The ISO file format is the base for derivation of all the above mentioned file formats (excluding the ISO file format itself). These file formats (including the ISO file format itself) are called the ISO family of file formats.

FIG. 2 shows a simplified file structure 220 according to the ISO base media file format. The basic building block in the ISO base media file format is called a box. Each box has a header and a payload. The box header indicates the type of the box and the size of the box in terms of bytes. A box may enclose other boxes, and the ISO file format specifies which box types are allowed within a box of a certain type. Furthermore, some boxes are mandatorily present in each file, while others are optional. Moreover, for some box types, it is allowed to have more than one box present in a file. It could be concluded that the ISO base media file format specifies a hierarchical structure of boxes.

According to ISO family of file formats, a file consists of media data and metadata that are enclosed in separate boxes, the media data (mdat) box and the movie (moov) box, respectively. For a file to be operable, both of these boxes must be present. The movie box may contain one or more tracks, and each track resides in one track box. A track can be one of the following types: media, hint, timed metadata. A media track refers to samples formatted according to a media compression format (and its encapsulation to the ISO base media file format). A hint track refers to hint samples, containing cookbook instructions for constructing packets for transmission over an indicated communication protocol. The cookbook instructions may contain guidance for packet header construction and include packet payload construction. In the packet payload construction, data residing in other tracks or items may be referenced, i.e. it is indicated by a reference which piece of data in a particular track or item is instructed to be copied into a packet during the packet construction process. A timed metadata track refers to samples describing referred media and/or hint samples. For the presentation one media type, typically one media track is selected. Samples of a track are implicitly associated with sample numbers that are incremented by 1 in the indicated decoding order of samples.

It is noted that the ISO base media file format does not limit a presentation to be contained in one file, but it may be contained in several files. One file contains the metadata for the whole presentation. This file may also contain all the media data, whereupon the presentation is self-contained. The other files, if used, are not required to be formatted to ISO base media file format, are used to contain media data, and may also contain unused media data, or other information. The ISO base media file format concerns the structure of the presentation file only. The format of the media-data files is constrained the ISO base media file format or its derivative formats only in that the media-data in the media files must be formatted as specified in the ISO base media file format or its derivative formats.

Movie fragments can be used when recording content to ISO files in order to avoid losing data if a recording application crashes, runs out of disk, or some other incident happens. Without movie fragments, data loss may occur because the file format insists that all metadata (the Movie Box) be written in one contiguous area of the file. Furthermore, when recording a file, there may not be sufficient amount of Random Access Memory (RAM) to buffer a Movie Box for the size of the storage available, and re-computing the contents of a Movie Box when the movie is closed is too slow. Moreover, movie fragments can enable simultaneous recording and playback of a file using a regular ISO file parser. Finally, smaller duration of initial buffering is required for progressive downloading, i.e. simultaneous reception and playback of a file, when movie fragments are used and the initial Movie Box is smaller compared to a file with the same media content but structured without movie fragments.

The movie fragment feature enables to split the metadata that conventionally would reside in the moov box to multiple pieces, each corresponding to a certain period of time for a track. In other words, the movie fragment feature enables to interleave file metadata and media data. Consequently, the size of the moov box can be limited and the use cases mentioned above be realized.

The media samples for the movie fragments reside in an mdat box, as usual, if they are in the same file as the moov box. For the meta data of the movie fragments, however, a moof box is provided. It comprises the information for a certain duration of playback time that would previously have been in the moov box. The moov box still represents a valid movie on its own, but in addition, it comprises an mvex box indicating that movie fragments will follow in the same file. The movie fragments extend the presentation that is associated to the moov box in time.

The metadata that can be included in the moof box is limited to a subset of the metadata that can be included in a moov box and is coded differently in some cases. Details of the boxes that can be included in a moof box can be found from the ISO base media file format specification.

In addition to timed tracks, ISO files can contain any non-timed binary objects in a meta box. The meta box can reside at the top level of the file, within a movie box, and within a track box, but at most one meta box may occur at each of the file level, movie level, or track level. The meta box is required to contain a ‘hdlr’ box indicating the structure or format of the ‘meta’ box contents. The meta box may list and characterize any number of binary items that can be referred and each one of them can be associated with a file name and are uniquely identified with the file by item identifier (item_id) which is a 16-bit unsigned integer value. The binary items are stored in an mdat box.

In order to support more than one meta box at any level of the hierarchy (file, movie, or track), a meta box container box (‘meco’) was introduced in Amendment 2 of the ISO base media file format. The meta box container box can carry any number of additional meta boxes at any level of the hierarchy (file, move, or track). This allows e.g. the same meta-data is being presented in two different, alternative, meta-data systems. The meta box relation box (‘mere’) enables describing how different meta boxes relate to each other, e.g. whether they contain exactly the same metadata (but described with different schemes) or if one represents a superset of another one.

In a recent “Technologies under Consideration” document for the ISO Base Media File Format (MPEG document N9378), it is no longer required that the binary items are located within a mdat box, but they can reside anywhere in a file—particularly in the meta box—and also within a second file.

The FLUTE/ALC Server File Format consists of features that are part of Amendment 2 of ISO Base Media File Format. In particular, the features include the possibility for calculating FEC repair symbols into FEC reservoirs stored as items in the file and providing packetization instructions (in the form of hint tracks) for generating FLUTE or ALC packets.

The FLUTE/ALC Server File Format supports multicast/broadcast delivery of files with FEC protection. Files to be delivered are stored as items in a container file (defined by the file format) and the meta box is amended with information on how the files are partitioned into source symbols. For each source block of a FEC encoding, additional parity symbols can pre-computed and stored as FEC reservoir items. The partitioning depends on the FEC scheme, the target packet size, and the desired FEC overhead. The actual transmission is governed by hint tracks that contain server instructions that facilitate the encapsulation of source and FEC symbols into packets. File Delivery (FD) hint tracks have been designed for the ALC/LCT (Asynchronous Layered Coding/Layered Coding Transport) and FLUTE (File Delivery over Unidirectional Transport) protocols.

File partitions and FEC reservoirs can be used independently of FD hint tracks and vice versa. The former aid the design of hint tracks and allow alternative hint tracks, e.g., with different FEC overheads, to re-use the same FEC symbols. They also provide means to access source symbols and additional FEC symbols independently for post-delivery repair, which may be performed over ALC/LCT or FLUTE or out-of-band via another protocol. In order to reduce complexity when a server follows hint track instructions, hint tracks refer directly to data ranges of items or data copied into hint samples.

The support for file delivery is designed to optimize the server transmission process by enabling ALC/LCT or FLUTE servers to follow simple instructions. It is enough to follow one pre-defined sequence of instructions per channel in order to transmit one session. The file format enables storage of pre-computed source blocks and symbol partitions, i.e., files may be partitioned into symbols which fit an intended packet size, and pre-computing a certain amount of FEC symbols that also can be used for post-session repair. The file format also allows storage of alternative ALC/LCT or FLUTE transmission session instructions that may lead to equivalent end results. Such alternatives may be intended for different channel conditions because of higher FEC protection or even by using different error correction schemes. Alternative sessions can refer to a common set of symbols. The hint tracks are flexible and can be used to compose FDT fragments and interleaving of such fragments within the actual object transmission. Several hint tracks can be combined into one or more sessions involving simultaneous transmission over multiple channels.

It is important to make a difference between the definition of sessions for transmission and the scheduling of such sessions. ALC/LCT and FLUTE server files only address optimization of the server transmission process. In order to ensure maximal usage and flexibility of such pre-defined sessions, all details regarding scheduling addresses, etc. are kept outside the definition of the file format. External scheduling applications decide such details, which are not important for optimizing transmission sessions per se. In particular, the following information is out-of-scope of the file format: time scheduling, target addresses and ports, source addresses and ports, and so-called Transport Session Identifiers (TSI).

The sample numbers associated with the samples of a file delivery hint track provide a numbered sequence. Hint track sample times provide send times of ALC/LCT or FLUTE packets for a default bitrate. Depending on the actual transmission bitrate, an ALC/LCT or FLUTE server may apply linear time scaling. Sample times may simplify the scheduling process, but it is up to the server to send ALC/LCT or FLUTE packets in a timely manner.

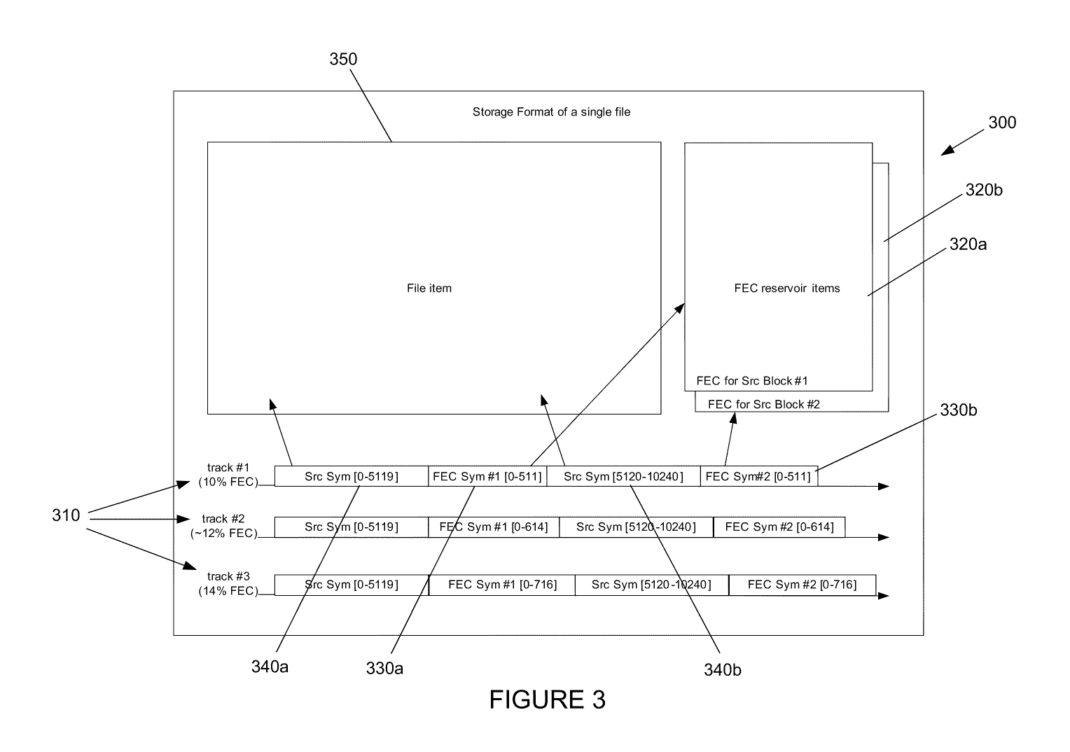

A schematic picture of a file 300 containing three alternative hint tracks with different FEC overhead for a source file is provided in FIG. 3. In this example, each source block 320a, 320b comprises only one sub-block 330a, 330b. Consequently, it is possible to include source symbols 340a, 340b by reference to the source file 350 (referred to as “File item” in FIG. 3)—e.g. a hint sample include instructions which byte range of the source file is copied into the respective packet.

The source file 350 in the example of FIG. 3 is partitioned into two source blocks containing symbols of a fixed size. FEC redundancy symbols are calculated for both source blocks and stored in separate FEC reservoir items. As the hint tracks reference the same items in the file there is no duplication of information. The original source symbols and FEC reservoirs can also be used by repair servers that don't use hint tracks.

A sample of an FD hint track is used to generate one or more FD packets. Each sample contains two areas: the instructions to compose the packets, and any extra data needed when sending those packets (e.g., encoding symbols that are copied into the sample instead of residing in items for source files or FEC). A sample of an FD hint track should not contain instructions for FD packets that are transmitted subsequently but rather a sample should describe packets that are transmitted virtually simultaneously.

The instructions to compose a packet contain three elements: LCT header template, LCT header extension constructor, and packet constructor. The LCT header template can be used by a server to form an LCT header for a packet. Some parts of the header depend on the server policy and are not included in the template. Some field lengths also depend on the LCT header bits assigned by the server. The server may also need to change the value of the Transport Object Identifier (TOI) of the LCT header template. The LCT header extension constructor contains the extension type and a copy of the header extension bytes, if any, to be included in the respective packet. The packet constructor provides the instructions to compose the payload for an FD packet. The following types of constructors are specified: no operation, immediate, track, item, and XML box. The no operation constructor can be used for padding of the packet payload to a desired length. The immediate constructor contains a copy of the data bytes to be included in the packet payload. The sample constructor is used to include a given byte range of a given sample of a given track into the packet payload. The item constructor is used to include a given byte range of a given item into the packet payload. The XML box constructor is used to include a given byte range of the XML box of the meta box into the packet payload.

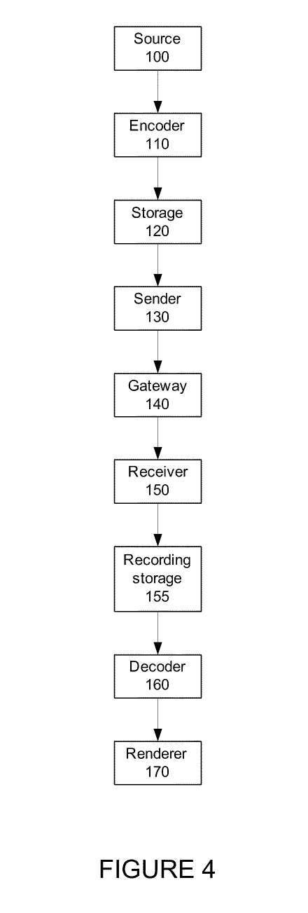

FIG. 4 is a graphical representation of a generic multimedia communication system within which various embodiments of the present invention may be implemented. As shown in FIG. 4, a data source 100 provides a source signal in an analog, uncompressed digital, or compressed digital format, or any combination of these formats. An encoder 110 encodes the source signal into a coded media bitstream. It should be noted that a bitstream to be decoded can be received directly or indirectly from a remote device located within virtually any type of network. Additionally, the bitstream can be received from local hardware or software. The encoder 110 may be capable of encoding more than one media type, such as audio and video, or more than one encoder 110 may be required to code different media types of the source signal. The encoder 110 may also get synthetically produced input, such as graphics and text, or it may be capable of producing coded bitstreams of synthetic media. In the following, only processing of one coded media bitstream of one media type is considered to simplify the description. It should be noted, however, that typically real-time broadcast services comprise several streams (typically at least one audio, video and text sub-titling stream). It should also be noted that the system may include many encoders, but in FIG. 4 only one encoder 110 is represented to simplify the description without a lack of generality. It should be further understood that, although text and examples contained herein may specifically describe an encoding process, one skilled in the art would understand that the same concepts and principles also apply to the corresponding decoding process and vice versa.

The coded media bitstream is transferred to a storage 120. The storage 120 may comprise any type of mass memory to store the coded media bitstream. The format of the coded media bitstream in the storage 120 may be an elementary self-contained bitstream format, or one or more coded media bitstreams may be encapsulated into a container file. Some systems operate “live”, i.e. omit storage and transfer coded media bitstream from the encoder 110 directly to the sender 130. The coded media bitstream is then transferred to the sender 130, also referred to as the server, on a need basis. The format used in the transmission may be an elementary self-contained bitstream format, a packet stream format, or one or more coded media bitstreams may be encapsulated into a container file. The encoder 110, the storage 120, and the server 130 may reside in the same physical device or they may be included in separate devices. The encoder 110 and server 130 may operate with live real-time content, in which case the coded media bitstream is typically not stored permanently, but rather buffered for small periods of time in the content encoder 110 and/or in the server 130 to smooth out variations in processing delay, transfer delay, and coded media bitrate.

The server 130 sends the coded media bitstream using a communication protocol stack. The stack may include but is not limited to Real-Time Transport Protocol (RTP), User Datagram Protocol (UDP), and Internet Protocol (IP). When the communication protocol stack is packet-oriented, the server 130 encapsulates the coded media bitstream into packets. For example, when RTP is used, the server 130 encapsulates the coded media bitstream into RTP packets according to an RTP payload format. Typically, each media type has a dedicated RTP payload format. It should be again noted that a system may contain more than one server 130, but for the sake of simplicity, the following description only considers one server 130.

The server 130 may or may not be connected to a gateway 140 through a communication network. The gateway 140 may perform different types of functions, such as translation of a packet stream according to one communication protocol stack to another communication protocol stack, merging and forking of data streams, and manipulation of data stream according to the downlink and/or receiver capabilities, such as controlling the bit rate of the forwarded stream according to prevailing downlink network conditions. Examples of gateways 140 include multipoint conference control units (MCUs), gateways between circuit-switched and packet-switched video telephony, Push-to-talk over Cellular (PoC) servers, IP encapsulators in digital video broadcasting-handheld (DVB-H) systems, or set-top boxes that forward broadcast transmissions locally to home wireless networks. When RTP is used, the gateway 140 is called an RTP mixer or an RTP translator and typically acts as an endpoint of an RTP connection.

The system includes one or more receivers 150, typically capable of receiving, de-modulating, and de-capsulating the transmitted signal into a coded media bitstream. The coded media bitstream is transferred to a recording storage 155. The recording storage 155 may comprise any type of mass memory to store the coded media bitstream. The recording storage 155 may alternatively or additively comprise computation memory, such as random access memory. The format of the coded media bitstream in the recording storage 155 may be an elementary self-contained bitstream format, or one or more coded media bitstreams may be encapsulated into a container file. If there are many coded media bitstreams, such as an audio stream and a video stream, associated with each other, a container file is typically used and the receiver 150 comprises or is attached to a container file generator producing a container file from input streams. Some systems operate “live,” i.e. omit the recording storage 155 and transfer coded media bitstream from the receiver 150 directly to the decoder 160. In some systems, only the most recent part of the recorded stream, e.g., the most recent 10-minute excerption of the recorded stream, is maintained in the recording storage 155, while any earlier recorded data is discarded from the recording storage 155.

The coded media bitstream is transferred from the recording storage 155 to the decoder 160. If there are many coded media bitstreams, such as an audio stream and a video stream, associated with each other and encapsulated into a container file, a file parser (not shown in the example of FIG. 4) is used to decapsulate each coded media bitstream from the container file. The recording storage 155 or a decoder 160 may comprise the file parser, or the file parser is attached to either recording storage 155 or the decoder 160.

The codec media bitstream is typically processed further by a decoder 160, whose output is one or more uncompressed media streams. Finally, a renderer 170 may reproduce the uncompressed media streams with a loudspeaker or a display, for example. The receiver 150, recording storage 155, decoder 160, and renderer 170 may reside in the same physical device or they may be included in separate devices.

The FLUTE/ALC Server File Format enables storage of source files for file delivery as items within a container file. The file format also enables storage of FEC repair data as FEC reservoirs, which are also items within a container file. A separate FEC reservoir is usually associated for each source block of a source file.

When MBMS FEC is used, symbols includes the concatenation of the sub-symbols which might not be a contiguous portion of the source file (see 3GPP TS 26.346 for more details). This happens when the source file size is bigger than the target sub-block size (the recommended value of which is 256 KB). In such a case, there is more than one sub-block for each source block. In this case, there are four possibilities to indicate the source symbols to be included into a packet. First, the source symbols can be copied in an immediate constructor. Second, the source symbols can be included in an extra data box of an FD hint sample, and a sample constructor referring to the hint track itself can be used to include them into a packet. The problem of the first and second approach is that the file then essentially contains a copy of the source file for each hint track—which causes significant increase of the file size. In the third approach, multiple item constructors are used to compose one packet, each constructor referring to a contiguous range of bytes within the source file stored as an item. The number of item constructors is typically equal to the number of sub-blocks. Hence, composing a packet with the third approach requires fetching of data from multiple locations of the source file, which may be inefficient in some systems, particularly in when data is obtained from a hard disk and the whole source file cannot be cached in random access memory. In the fourth approach, rather than storing the source files as items in the container file, each source block of a source file can be stored as a separate item. The problem of this fourth approach is that the file format does not provide means to identify source blocks for source files, and source blocks could be misinterpreted as source files.

Embodiments of the present invention can relate to the FLUTE/ALC Server File Format, specified as a part of Amendment 2 of the ISO Base Media File Format. In particular, embodiments of the present invention relate to storage of source files or source blocks as items in a container file. However, the FLUTE/ALC Server File Format fails to include identification of whether items are source files or source blocks.

According to certain embodiments of the present invention, it is explicitly indicated in a file if an item is a source block.

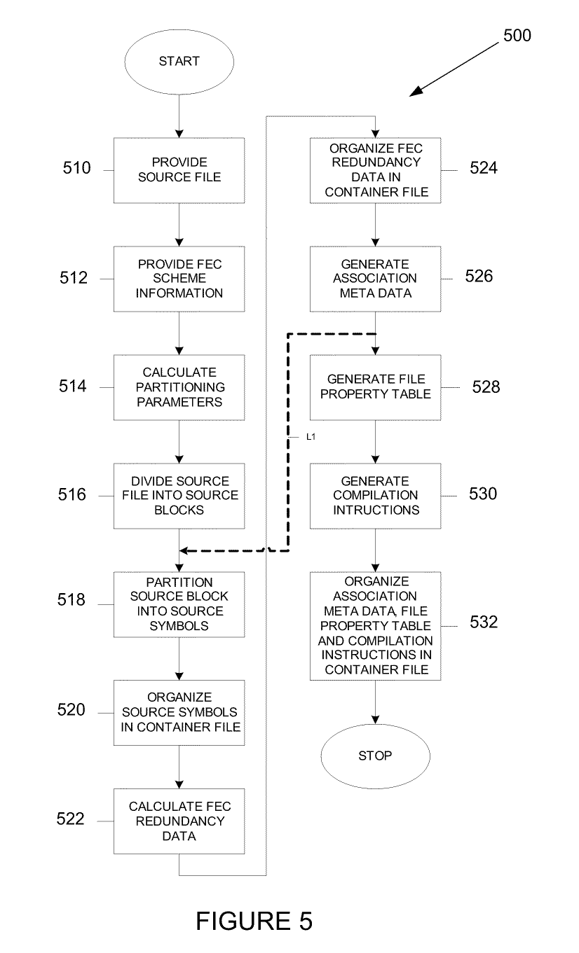

FIG. 5 illustrates an exemplary flow diagram showing a media container file generation method according to an embodiment of the present invention. The method starts with at least one source file being provided to be added into the media container file (block 510). Information about the intended FEC scheme is provided at block 512, to be able to calculate partitioning parameters for the source file at block 514. The source file is divided into source blocks according to the calculated partitioning parameters (block 516). Each created source block is then handled through block 518-526. The processed source block is partitioned into source symbols according to the partitioning parameters (block 518). At block 520, source symbols of the processed source block are organized in the media container file as an elementary item, e.g. as a binary item according to the ISO base media file format, and the item containing the source symbols for a source block is referred to as a File reservoir. At block 522, FEC redundancy data is calculated based on the source symbols composed in block 518. Next, at block 524, FEC redundancy data is organized into the media container file as an FEC reservoir item. Association meta data between source symbols and FEC redundancy data is generated (block 526). If the source file is divided into more than one source block, then block 518-526 are repeated for each source block, as illustrated by the dotted line returning to block 518. So, if there are N source blocks for a particular source file, then there exist N File and N FEC reservoir items for the particular source file in the media container file.

At block 528, a file property table containing information about inserted source files is generated. In this table for example information about content type, content encoding, content length, content location, MD5 digest and file partitioning parameters for each source file can be presented. Also information about actual storage location of each reservoir items and associations between File and FEC reservoirs per each source file is usually recorded into the file property table. At block 530, compilation instructions to be used by media server are generated. These instructions can be used as hints how to compose transmittable packet stream using reservoir items stored in the media container file. In practice, the compilation instructions can be FD hint tracks. An FD hint sample to form a transmittable packet can refer to an indicated byte range in a File reservoir item indicated by its item identifier. Then, at block 532, generated association meta data, file property table and compilation instructions are organized into the media container file.

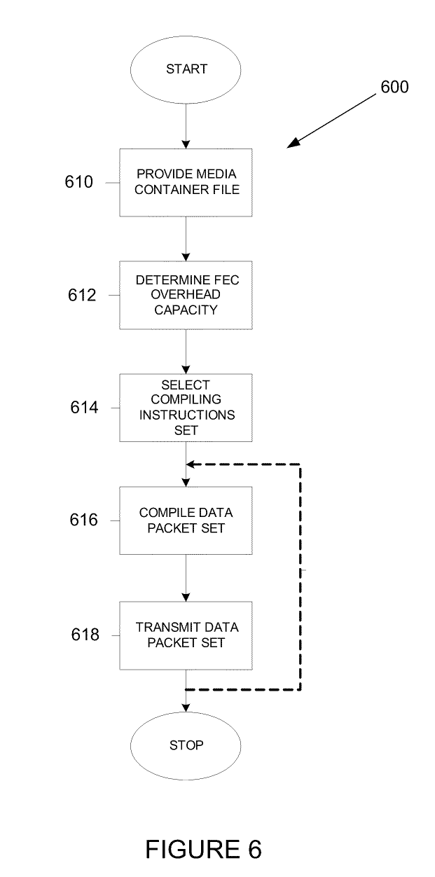

FIG. 6 illustrates an exemplary flow diagram showing a media server operation method in accordance with embodiments of the present invention. The method starts with a media container file being provided to a media server (block 610). At block 612, the media server determines FEC overhead capacity which is possible to be used with media session in question. Using this information suitable compiling instructions set among available alternatives is selected (block 614). The media container file contains pre-composed source symbols and pre-calculated repair symbols as File reservoirs and FEC reservoirs, respectively, so there is no need to source symbol construction and FEC encoding on the fly. Instead of that, the media server uses compiling instructions, meta data, and reservoir items to compile data packet set (block 616). Compiled data packet set is then transmitted to the clients (block 618). It is not necessary for the media server to compile all data packets belonging to the selected compiling instruction set once. It is possible to repeat blocks 616 and 618 several times. This is illustrated by the dotted return line to block 616 in the example of FIG. 6. When all data packets are transmitted, the method ends.

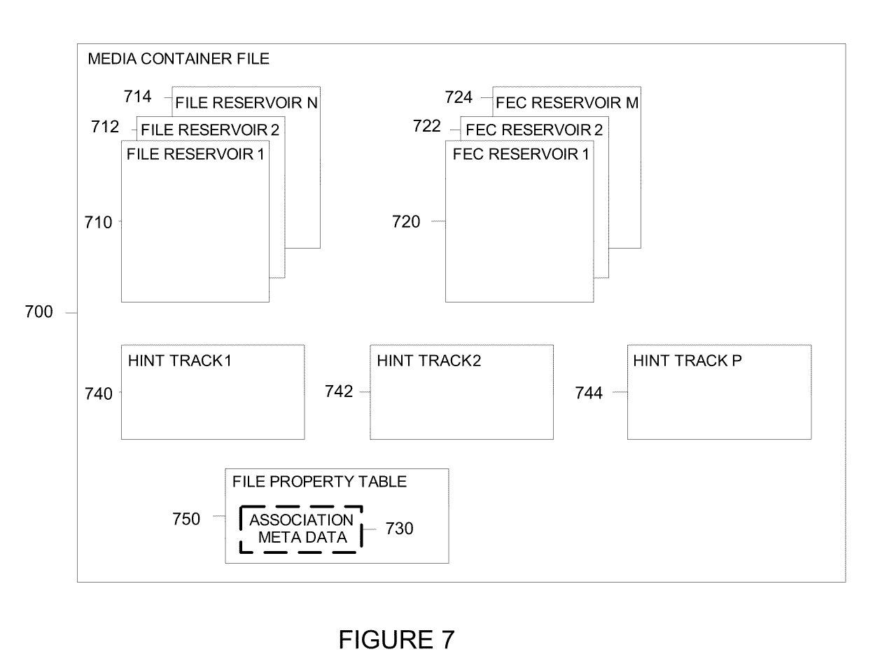

FIG. 7 illustrates an exemplary media container file 700. The media container file 700 contains three File reservoirs labeled File reservoir 1, 2, and N (710, 712, and 714, respectively) and an equal amount of FEC reservoirs labeled FEC reservoir 1, 2, and M (720, 722, and 724, respectively). In a general case, any number N File reservoirs and M FEC reservoirs can be stored in a media container file, and typically N equals to M. When the media container file is formatted according to the ISO base media file format, each File reservoir and FEC reservoir is a binary item of the ISO base media file format. Each File reservoir contains a source block derived from a source file based on particular partitioning information. The file property table 750 can be formatted similarly to the FD Item Information Box of the ISO base media file format. It contains association meta data 730 to identify items that are File reservoirs, i.e. contain source blocks, and items that are FEC reservoirs. In addition, the association meta data 730 logically links each respective pair of a File reservoir and FEC reservoir with each other, i.e. the source symbols of a source blocks and the FEC repair symbols derived from the source block. In practice, the association meta data 730 can be a loop or a table of partition entries as described below. The media container file may additionally comprise any number of hint tracks for instructing in deriving packets from File and FEC reservoirs for file delivery. The hint tracks can be formatted according to the FD hint tracks of the ISO base media file format.

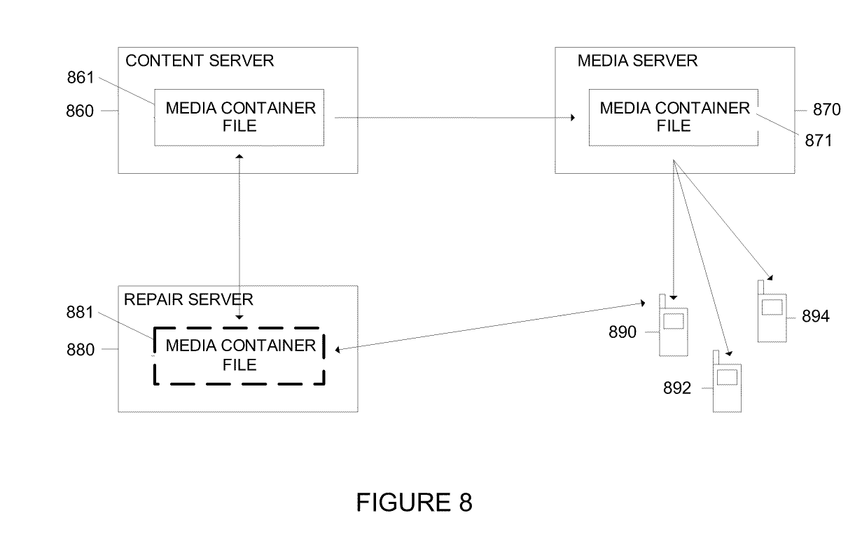

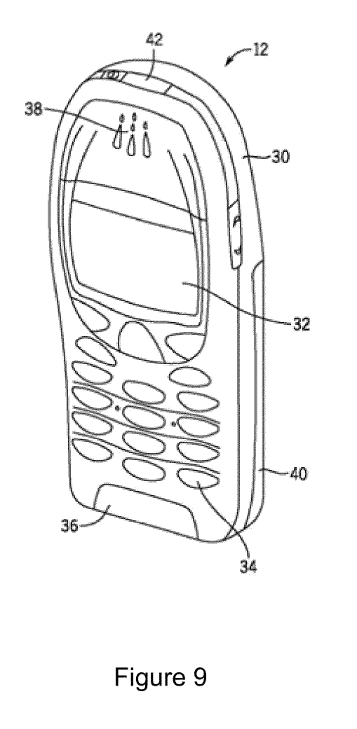

FIG. 8 illustrates an exemplary communication system using a media container file in accordance with embodiments of the present invention. A content server 860 illustrates a content provider who creates the media container file. A media server 870 gets a copy of the media container file and uses it for compiling data packet stream (source and repair symbols) to be sent to the clients 890, 892, 894. If a client 890, 892, 894 is not able to reconstruct the source file completely, it may contact a repair server 880, typically after the session for the broadcast/multicast file transfer has been completed. An example of a communication protocol and mechanism between a client and a repair server is included in 3GPP Technical Specification 26.346. The repair server 880 can obtain a copy of the media container file from the content server. The existing source and repair symbols included in the media container file can be used in a post-session repair procedure between a client and the repair server.

Thus, embodiments of the present invention provide advantages over the prior art. Specifically, while prior-art approaches where source symbols are copied in an immediate constructor or in an extra data box of an FD hint sample essentially require a copy of a source file (organized as source blocks) per each hint track, embodiments of the present invention require only one copy of a source file (organized as source blocks), regardless of the number of hint tracks, as long as the source file partitioning remains the same. The file size is, therefore, significantly reduced when multiple hint tracks are used to provide several error protection strengths. For example, when an original file (JPEG, 464 KB) is stored and three hint tracks (FEC overheads 50%, 100% and 200%) are provided, file sizes for the ISO file are 2046 KB with File reservoirs and 2986 KB without. Embodiments of the present invention allow storing of source blocks as items in a container file and identify explicitly that an item is a source block. According to one prior-art approach, an FD hint sample can contain instructions which parts of a source file are copied to a packet. This, however, requires reading a source file from multiple positions and hence accessing the file multiple times. The invention requires only one read operation per one packet.

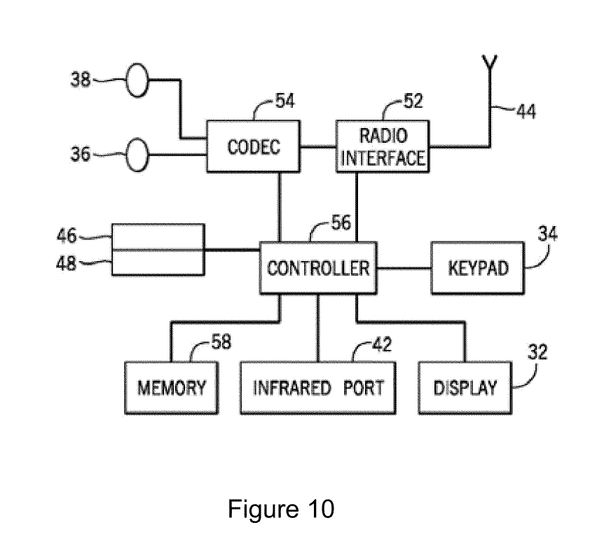

FIGS. 9 and 10 show one representative electronic device 12 which may serve as a client station and within which embodiments of the present invention may be implemented. It should be understood, however, that the present invention is not intended to be limited to one particular type of electronic device 12. The electronic device 12 of FIGS. 9 and 10 includes a housing 30 which forms the exterior of the device. The housing 30 may protect certain components from the external environment and provides a user with access to other components. A display 32 is provided in the form of a liquid crystal display, for example, to allow the user to view text, images, video and the like.

A keypad 34 and a microphone 36 allow user inputs to be received by the electronic device 12. The keypad 34 may be used to enter alphanumeric inputs by the user, while the microphone 36 may be used to either provide audio inputs to the electronic device 12 or to allow the user to verbally communicate through a network. An ear-piece 38 allows a user to verbally communicate with another user. The electronic device 12 is powered by a battery 40, which is preferably a rechargeable battery. The microphone 36 and the ear piece 38 may be coupled to codec circuitry 54, which may be coupled to a device controller 54 and a radio interface 52.

An infrared port 42 may be provided to allow communication with nearby devices, for example. The electronic device 12 may communicate with a network through, for example, a base station via radio communication which may be facilitated by an antenna 44. The antenna 44 may be tuned for communication at one or more ranges of frequencies. The antenna 44 may be coupled to the radio interface circuitry 52, which is coupled to the controller 56 and the codec circuitry 54. In this regard, the controller 56 may be a central processing unit for controlling the operation of the electronic device 12.

The electronic device 12 may be adapted to incorporate a smart card 46 to identify the user and to provide secure communication, for example. A card reader 48 may be provided to read the smart card 46 and to relay the information from the smart card 46 to the device controller 56. A storage unit, such as memory 58, may be provided to store data (e.g., contact list) or programs to be accessed by the controller 56.

Various embodiments described herein are described in the general context of method steps or processes, which may be implemented in one embodiment by a computer program product, embodied in a computer-readable medium, including computer-executable instructions, such as program code, executed by computers in networked environments. A computer-readable medium may include removable and non-removable storage devices including, but not limited to, Read Only Memory (ROM), Random Access Memory (RAM), compact discs (CDs), digital versatile discs (DVD), etc. Generally, program modules may include routines, programs, objects, components, data structures, etc. that performs particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps or processes.

Software and web implementations of various embodiments can be accomplished with standard programming techniques with rule-based logic and other logic to accomplish various database searching steps or processes, correlation steps or processes, comparison steps or processes and decision steps or processes. It should be noted that the words “component” and “module,” as used herein and in the following claims, is intended to encompass implementations using one or more lines of software code, and/or hardware implementations, and/or equipment for receiving manual inputs.

The foregoing description of embodiments has been presented for purposes of illustration and description. The foregoing description is not intended to be exhaustive or to limit embodiments of the present invention to the precise form disclosed, and modifications and variations are possible in light of the above teachings or may be acquired from practice of various embodiments. The embodiments discussed herein were chosen and described in order to explain the principles and the nature of various embodiments and its practical application to enable one skilled in the art to utilize the present invention in various embodiments and with various modifications as are suited to the particular use contemplated. The features of the embodiments described herein may be combined in all possible combinations of methods, apparatus, modules, systems, and computer program products.

What is claimed is:

1. A method of generating a media container file, comprising:
organizing a first media source block in the media container file;
calculating forward error correction (FEC) redundancy data based on the first media source block;
organizing the FEC redundancy data in at least one FEC reservoir in the media container file;
providing, in the media container file, meta data providing an association between the first media source block and the at least one FEC reservoir;
storing the first media source block as a first elementary item in the media container file; and
providing, in the media container file, information that the first elementary item comprises the first media source block.

2. The method of claim 1, further comprising:
providing a media source file; and
organizing the media source file into the first media source block and any number of other media source blocks.

3. The method of claim 2, wherein the first media source block more than one contiguous portion of the media source file.

4. A media content server, comprising:
a media block manager for organizing a first media source block in the media container file;
a forward error correction (FEC) codec for calculating FEC redundancy data based on the first media source block;
an FEC data manager coupled to the FEC codec for organizing the FEC redundancy data in at least one FEC reservoir in the media container file;
a meta data manager for providing, in the media container file, meta data providing an association between the first media source block and the at least one FEC reservoir;
a media container file manager for storing the first media source block as a first elementary item in the media container file; and
a media source block information manager for providing, in the media container file, information that the first elementary item comprises the first media source block.

5. An apparatus, comprising:
a processor; and
a memory unit communicatively connected to the processor and including:
computer code for organizing a first media source block in the media container file;
computer code for calculating forward error correction (FEC) redundancy data based on the first media source block;
computer code for organizing the FEC redundancy data in at least one FEC reservoir in the media container file;
computer code for providing, in the media container file, meta data providing an association between the first media source block and the at least one FEC reservoir;
computer code for storing the first media source block as a first elementary item in the media container file; and
computer code for providing, in the media container file, information that the first elementary item comprises the first media source block.

6. A program product, embodied on a computer-readable medium, comprising computer code for performing the following steps:
organizing a first media source block in the media container file;
calculating forward error correction (FEC) redundancy data based on the first media source block;
organizing the FEC redundancy data in at least one FEC reservoir in the media container file;
providing, in the media container file, meta data providing an association between the first media source block and the at least one FEC reservoir;
storing the first media source block as a first elementary item in the media container file; and
providing, in the media container file, information that the first elementary item comprises the first media source block.
